(19) United States
(12) Patent Application Publication
(10) Pub. No.: US 2021/0389055 A1
(43) Pub. Date: Dec. 16, 2021

(54) COMPOUND WICK STRUCTURE OF VAPOR CHAMBER

(71) Applicant: ASIA VITAL COMPONENTS CO., LTD., New Taipei City (TW)

(72) Inventors: Jian Zhang, New Taipei City (TW); Xi-Wen Xiong, New Taipei City (TW); Hu-Xing Lai, New Taipei City (TW)

(21) Appl. No.: 16/901,011

(22) Filed: Jun. 15, 2020

(51) Int. Cl. F28D 15/04

(52) U.S. Cl. CPC F28D 15/046; F28D 15/0233

(57) ABSTRACT

The present invention provides a compound wick structure of a vapor chamber, which comprises a first plate and a second plate. The first plate has a first side and a second side. The second plate has a third side and a fourth side. The first plate and the second plate are assembled together to form a sealed chamber. The third side of the second plate is provided with a mesh or a fiber body; the third side has at least one heated zone having a first sintered-powder structure. The first sintered-powder structure is selected to be connected to or in contact with the mesh or the fiber body. A working liquid is disposed in the sealed chamber. By means of the arrangement of the compound wick structure, the vertical and horizontal flow-back efficiencies of the working liquid are enhanced and the efficiency of liquid-vapor cycle is increased.

### BACKGROUND OF THE INVENTION

### 1. Field of the Invention

The present invention relates to a compound wick structure of a vapor chamber and in particular to a compound wick structure of a vapor chamber, which combines a mesh and sintered powder or other kinds of wick structures with two-phase properties

### 2. Description of Prior Art

The current vapor chamber is a heat-transfer device via two-phase heat exchange and is commonly applied in the heat transfer between the surfaces with large areas. Due to large contact area, the rapid and uniform heat transfer between the surfaces can be achieved.

There is a sealed chamber inside the vapor chamber. The side of the sealed chamber in contact with the heat source is provided with a wick structure for absorbing water and flow-back of water. In addition, when a vacuum is created in the sealed chamber, a working liquid is disposed inside the sealed chamber for two-phase heat exchange. The wick structure of the traditional vapor chamber with better capillary attraction mostly selects sintered powder to be formed on the surface of the sealed chamber using a sintering process. The sintered powder has porous structure inducing capillary attraction, which returns the condensed working liquid back or makes it absorbed in the heated zone (i.e., the evaporator).

After the working liquid in the evaporator of the vapor chamber is heated and evaporated to diffuse to the condenser and then is condensed to a liquid state. Next, the droplets of the working liquid drip by gravity to be absorbed by the wick structure made of sintered powder to flow back to the evaporator. The traditional wick structure made of sintered powder has poor flow-back efficiency for the horizontal working liquid. If the whole area of the vapor chamber is disposed in a wide and long pattern, the flow-back efficiency in the horizontal direction becomes poor. Therefore, how to obtain higher flow-back efficiency, both in the vertical and horizontal directions, of the vapor chamber is the target which the vendors want to achieve.

### SUMMARY OF THE INVENTION

A main objective of the present invention is to provide a compound wick structure of a vapor chamber, which combines the properties of various wick structures such that the present invention has the properties of various vapor-liquid cycles provided by plural wick structures.

To achieve the above objective, the present invention provides a compound wick structure of a vapor chamber, which comprises a first plate and a second plate.

The first plate has a first side and a second side. The second plate has a third side and a fourth side. The first plate and the second plate are assembled together to form a sealed chamber. The third side of the second plate is provided with a mesh or a fiber body. The third side has at least one heated zone which has a first sintered-powder structure; the first sintered-powder structure is selected to be connected to or in contact with the mesh or the fiber body. A working liquid is disposed in the sealed chamber.

The present invention uses the capillary properties provided by the wick structure such as the mesh and the fiber body combined with the sintered powder to apply the properties of the above two members and overcome the drawbacks thereof. Consequently, the efficiency of liquid-vapor cycle of the vapor chamber is improved.

### BRIEF DESCRIPTION OF DRAWING

FIG. 1a is a perspective view of the compound wick structure of a vapor chamber according to the first embodiment of the present invention;

FIG. 1b is a perspective view of the compound wick structure of a vapor chamber according to the first embodiment of the present invention;

FIG. 2 is an assembled cross-sectional view of the compound wick structure of a vapor chamber according to the first embodiment of the present invention;

FIG. 3 is an assembled cross-sectional view of the compound wick structure of a vapor chamber according to the second embodiment of the present invention;

FIG. 4 is an assembled cross-sectional view of the compound wick structure of a vapor chamber according to the third embodiment of the present invention; and

FIG. 5 is an assembled cross-sectional view of the compound wick structure of a vapor chamber according to the fourth embodiment of the present invention.

### DETAILED DESCRIPTION OF THE INVENTION

The above objective of the present invention and the features of structure and function of the present invention are described according to the preferred embodiments in accompanying figures.

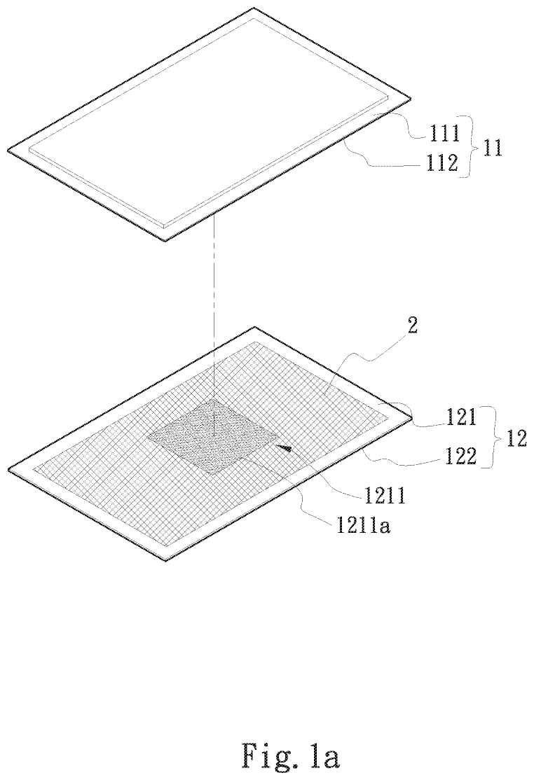

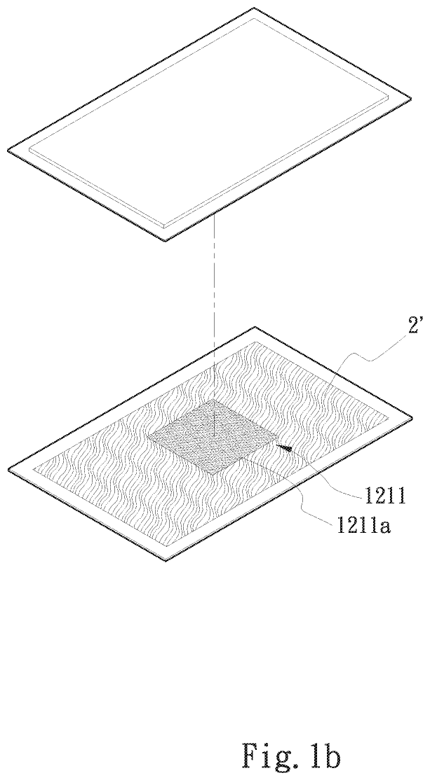

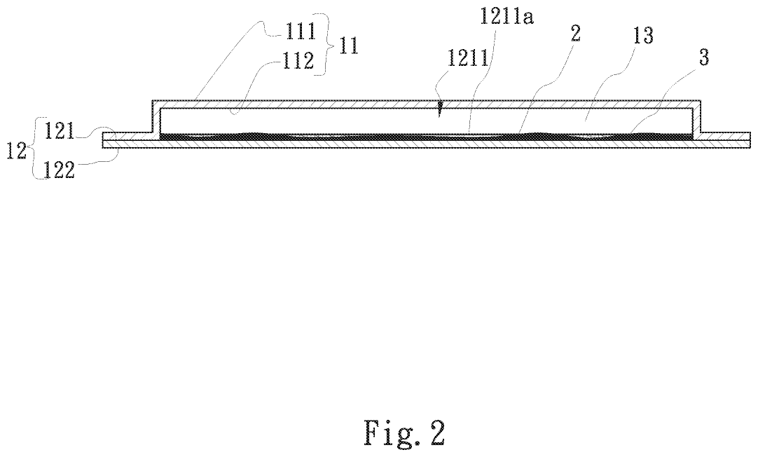

Please refer to FIGS. 1a, 1b, and 2, which are the perspective views and the assembled cross-sectional view of the compound wick structure of a vapor chamber according to the first embodiment of the present invention. As shown in FIGS. 1a, 1b, and 2, the compound wick structure of the vapor chamber comprises a first plate 11 and a second plate 12.

The first plate 11 has a first side 111 and a second side 112. The first side 111 and the second side 112 are disposed on the top side and the bottom side of the first plate 11, respectively.

The second plate 12 has a third side 121 and a fourth side 122. The third side 121 and the fourth side 122 are disposed on the top side and the bottom side of the second plate 12, respectively. The first plate 11 and the second plate 12 are assembled together to form a sealed chamber 13. The third side 121 of the second plate 12 is provided with a mesh 2; the third side 121 has at least one heated zone 1211. The heated zone 1211 has a first sintered-powder structure 1211a which is selected to be connected to or in contact with the mesh 2 or the fiber body 2′ (see FIG. 1b). In the current embodiment, the first sintered-powder structure 1211a in contact with the mesh 2 is used as an example for explanation. Also, the first sintered-powder structure 1211a can be partly in contact with and partly connected to the mesh 2, but not limited to this. That is, the mesh 2 or fiber body 2′ (see FIG. 1b) is disposed at the edge of the first sintered-powder structure 1211a to circle about it and extend outwards. In addition, a working liquid 3 is disposed in the sealed chamber 13.

In the current embodiment, the heated zone 1211 is selected to be disposed near the center of the second plate 12 and the first sintered-powder structure 1211a is sintered to form a square shape in the heated zone 1211.

The first plate 11 and the second plate 12 are made of copper, aluminum, stainless steel, ceramic, commercially pure titanium, titanium alloy, copper alloy, or aluminum alloy; the first plate 11 and the second plate 12 are made of the same or different materials.

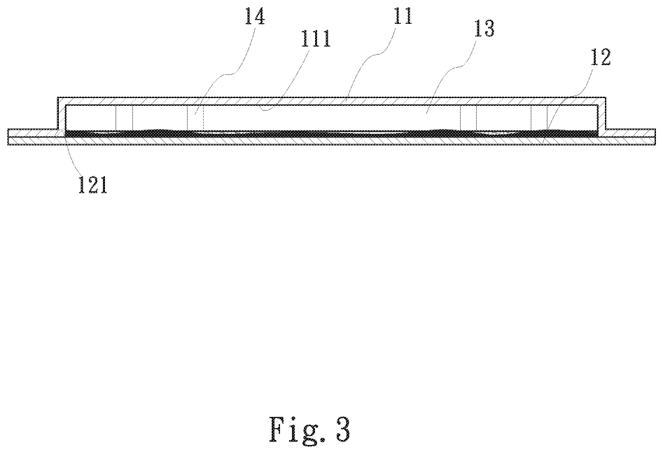

Please refer to FIG. 3, which is an assembled cross-sectional view of the compound wick structure of a vapor chamber according to the second embodiment of the present invention. As shown in FIG. 3, the structure of the current embodiment is generally identical to that of the first embodiment and will not be repeated hereafter. The difference is that, in the current embodiment, a support structure 14 is disposed in the sealed chamber 13 and is composed of a plurality of solid cylinders, hollow rings, or sintered-powder posts. Moreover, two ends of the support structure 14 individually hold the second side 112 and the third side 121. In this way, the sealed chamber 13 of the vapor chamber is reinforced to prevent collapse.

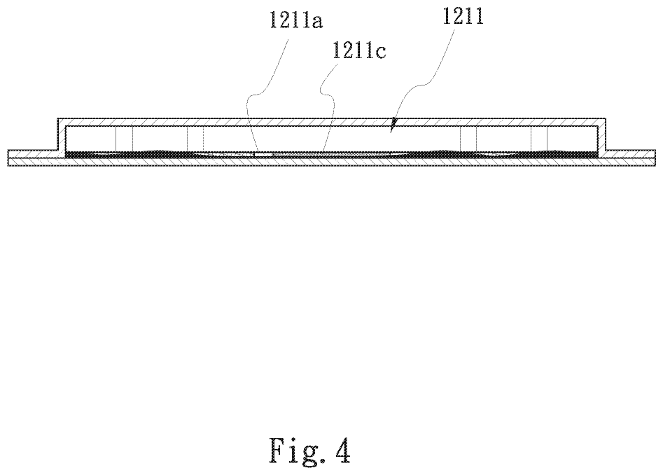

Please refer to FIG. 4, which is an assembled cross-sectional view of the compound wick structure of a vapor chamber according to the third embodiment of the present invention. As shown in FIG. 4, the structure of the current embodiment is generally identical to that of the first embodiment and will not be repeated hereafter. The difference is that, in the current embodiment, a second sintered-powder structure 1211c is disposed at the center of the first sintered-powder structure 1211a and the porosity of the first sintered-powder structure 1211a is larger than that of the second sintered-powder structure 1211c. In this way, the water content in the heated zone 1211 is increased through the sintered powders with different porosities.

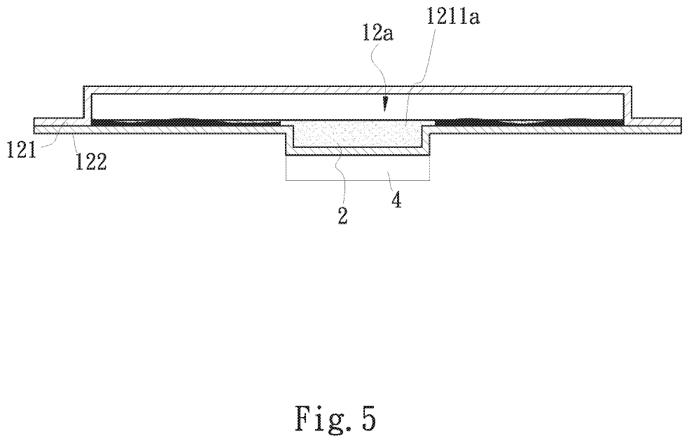

Please refer to FIG. 5, which is an assembled cross-sectional view of the compound wick structure of a vapor chamber according to the fourth embodiment of the present invention. As shown in FIG. 5, the structure of the current embodiment is generally identical to that of the first embodiment and will not be repeated hereafter. The difference is that, in the current embodiment, a recess 12a is formed at the center of the heated zone 1211 of the second plate 12 by protruding the third side 121 of the second plate 12 towards the fourth side 122. The first sintered-powder structure 1211a is filled in the recess 12a such that the first sintered-powder structure 1211a is flush with, below, or above the third side 121. In the current embodiment, the downward projection of the fourth side 122 caused by the disposition of the recess 12a is in contact with a heat source 4 can increase the heat transfer efficiency with the heat source 4.

The above-mentioned embodiments of the present invention combine the mesh or the fiber body with the sintered-powder structure, which can enhance the horizontal flow-back capability of the vapor chamber through the mesh or the fiber body. Furthermore, the water content of the heated zone is increased by means of the sintered-powder structures to prevent the situation of dry-heating. Consequently, the combined application of compound wick structure of the present invention further overcomes the disadvantage of the traditional vapor chamber having the vapor-liquid cycle only in the vertical direction, but not in the horizontal direction.

What is claimed is:

1. A compound wick structure of a vapor chamber, comprising:
a first plate having a first side and a second side; and
a second plate having a third side and a fourth side, wherein the first plate and the second plate are assembled together to form a sealed chamber, wherein the third side of the second plate is provided with a mesh or a fiber body, wherein the third side has at least one heated zone which has a first sintered-powder structure, wherein the first sintered-powder structure is selected to be connected to or in contact with the mesh or the fiber body, wherein a working liquid is disposed in the sealed chamber.

2. The compound wick structure of a vapor chamber according to claim 1, wherein a support structure is disposed in the sealed chamber and is composed of a plurality of solid cylinders, hollow rings, or sintered-powder posts, wherein two ends of the support structure individually hold the second side and the third side.

3. The compound wick structure of a vapor chamber according to claim 1, wherein a second sintered-powder structure is disposed at the center of the first sintered-powder structure, wherein the porosity of the first sintered-powder structure is larger than that of the second sintered-powder structure.

4. The compound wick structure of a vapor chamber according to claim 1, wherein the first plate and the second plate are made of copper, aluminum, stainless steel, ceramic, commercially pure titanium, titanium alloy, copper alloy, or aluminum alloy, wherein the first plate and the second plate are made of the same or different materials.
